(19) United States
(12) Patent Application Publication
(10) Pub. No.: US 2011/0186324 A1
(43) Pub. Date: Aug. 4, 2011

(54) ELECTROMAGNETIC INTERFERENCE SUPPRESSING HYBRID SHEET

(76) Inventors: Eun-Kwang Hur, Seoul (KR); Jung-Ju Suh, Seoul (KR); Jung-Hwan Lee, Seoul (KR)

(21) Appl. No.: 13/061,732

(22) PCT Filed: Sep. 2, 2009
(86) PCT No.: PCT/US2009/055703

§ 371 Date: Apr. 25, 2011

(30) Foreign Application Priority Data
Sep. 4, 2008 (KR) 10-2008-0087370

(51) Int. Cl. H01B 11/06; H05K 9/00; B05D 5/12

(52) U.S. Cl. 174/34; 174/391; 427/126.1

(57) ABSTRACT

Disclosed is an electromagnetic interference suppressing hybrid sheet including an electromagnetic wave absorbing layer including ferrite particles, which is laminated on one side of an electromagnetic wave shielding layer including an electro-conductive material, thereby protecting an electronic device from an electromagnetic wave generated from inside and/or outside of the electronic device.

### TECHNICAL FIELD

The present invention relates to a hybrid sheet for suppressing electromagnetic interference, and more particularly to a hybrid sheet for suppressing an electromagnetic wave, which includes an antistatic function by a grounding function as well as an electromagnetic wave shielding/absorbing function.

### BACKGROUND

Recently, the use of electronic devices such as cellular phones, digital cameras, notebook computers, full HD PDP/LCD TVs, etc. has increased. Also, the use of a high speed data cable having a wireless communication function for interoperation between the devices, and a high speed processing function of voice/image signal of high capacity, has increased. However, such an electronic device has had a tendency to be digitalized, miniaturized, and thin, and thus has emitted a large amount of electromagnetic waves according to its use and the use environment, thereby causing interference to peripheral devices of the electronic device. Also, in the electronic device, interference occurs by electromagnetic waves emitted from other external electronic devices.

In general, in order to suppress such interference by an electromagnetic wave, that is, electromagnetic interference (EMI), an electromagnetic wave shielding means or an electromagnetic wave absorbing means is disposed inside or outside of an electronic device. Especially, the electromagnetic wave shielding means or the electromagnetic wave absorbing means is disposed inside or outside of the electronic device, so that the electromagnetic wave generated within the electronic device is not emitted to the outside, the amount of the electromagnetic wave transferred from one electronic device to another electronic device through a transferring route (e.g., a wired/wireless cable) is minimized, or the electromagnetic wave generated from an external electronic device does not reach the inside.

As the electromagnetic wave shielding means, a copper plate or an aluminum plate has been conventionally used. When an electromagnetic wave is incident on the surface of the electromagnetic wave shielding means, some of the electromagnetic wave is changed into current on the surface of the electromagnetic wave shielding means, and is emitted along the surface to the outside, thereby shielding the device from the electromagnetic wave. However, some of the electromagnetic wave cannot be shielded by the electromagnetic wave shielding means, and passes through the electromagnetic wave shielding means to adversely affect an electronic device.

Meanwhile, as the electromagnetic wave absorbing means, a certain material, such as carbon, graphite, or sendust, dispersed in a binder resin, has been used. However, such an electromagnetic wave absorbing means can absorb only an electromagnetic wave having a frequency of a certain band, but allows most of the electromagnetic wave to pass through.

As described above, a conventionally known electromagnetic wave suppressing means has included only one of an electromagnetic wave shielding function and an electromagnetic wave absorbing function, but not both of them.

### SUMMARY

Therefore, the present invention has been made in view of the above-mentioned problems. The present invention provides a hybrid sheet for suppressing an electromagnetic wave, which can protect an electronic device from an electromagnetic wave generated from the outside, and can suppress the transfer of the electromagnetic wave generated within the electronic device to the outside. Also, the present invention provides a thin electromagnetic interference suppressing hybrid sheet having a thickness of about 10° μm or less.

In accordance with an aspect of the present invention, there is provided an electromagnetic interference suppressing hybrid sheet including: an electromagnetic wave shielding layer containing an electro-conductive material; and an electromagnetic wave absorbing layer containing ferrite particles, which is laminated on one side of the electromagnetic wave shielding layer.

In the electromagnetic interference suppressing hybrid sheet of the present invention, on one side of an electromagnetic wave shielding layer including an electro-conductive material, an electromagnetic wave absorbing layer including ferrite particles is laminated, thereby protecting an electronic device from an electromagnetic wave generated from inside and/or outside of the electronic device.

### BRIEF DESCRIPTION OF THE DRAWINGS

FIG. 1 is a cross-sectional view of an electromagnetic interference suppressing hybrid sheet according to an embodiment of the present invention.

FIGS. 2 to 6 are cross-sectional views of electromagnetic interference suppressing hybrid sheets according to other embodiments of the present invention.

FIGS. 7 and 7A are perspective views of a cable having the electromagnetic interference suppressing hybrid sheet of the present invention.

FIG. 8 is a digital image of plate-type ferrite particles used for the electromagnetic interference suppressing hybrid sheet of the present invention, taken by SEM (scanning electron microscopy).

FIG. 9 is a graph illustrating the shielding effectiveness of an electromagnetic interference suppressing hybrid sheet obtained from Example 1.

FIG. 10 is a graph illustrating power loss in the electromagnetic interference suppressing hybrid sheet obtained from Example 1.

FIG. 11 is a graph illustrating magnetic permeability of the electromagnetic interference suppressing hybrid sheet obtained from Example 1.

FIG. 12 is a graph illustrating suppression of Radiation-Noise in the data cable applied with the electromagnetic interference suppressing hybrid sheet obtained from Example 1.

### DETAILED DESCRIPTION OF THE INVENTION

Hereinafter, embodiments of the present invention will be described in detail.

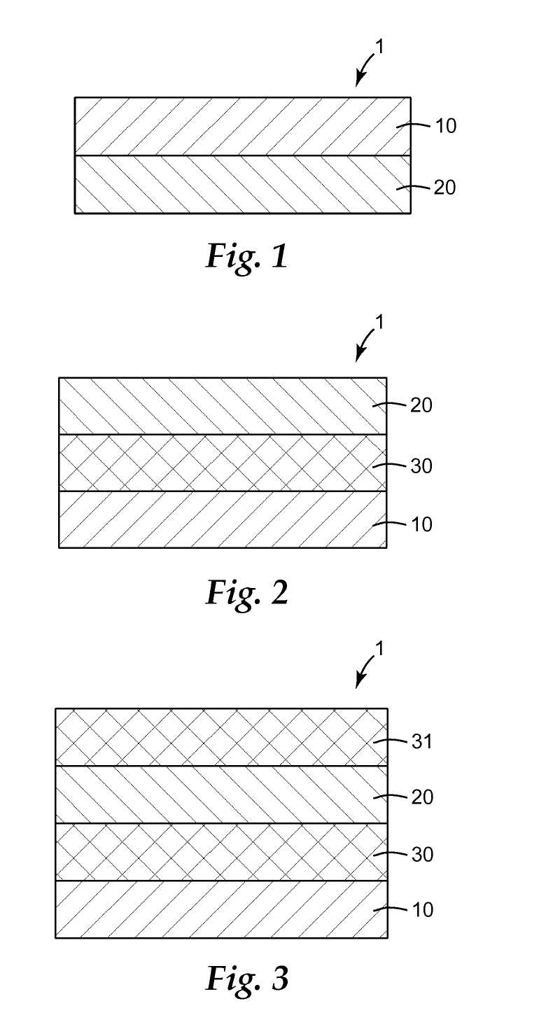

A sheet according to the present invention includes an electromagnetic wave absorbing layer 20 containing ferrite particles that is laminated on one side of an electromagnetic wave shielding layer 10 containing an electro-conductive material, thereby protecting an electronic device from electromagnetic interference generated from the inside and/or outside thereof (see FIG. 1). The sheet may be disposed in an electronic device, in which the electromagnetic wave absorbing layer 20 is contacted with the outer surface of the electronic device, and the electromagnetic wave shielding layer 10 is laminated on the outer surface of the electromagnetic wave absorbing layer 20, or else the electromagnetic wave shielding layer 10 is contacted with the outer surface of the electronic device, and the electromagnetic wave absorbing layer 20 is laminated on the outer surface of the electromagnetic wave shielding layer 10.

For example, when an electromagnetic wave absorbing layer 20 is contacted with the outer surface of an electronic device, and an electromagnetic wave shielding layer 10 is laminated on the outer surface of the electromagnetic wave absorbing layer 20, an electromagnetic wave generated from the outside of the electronic device is incident to the electromagnetic wave shielding layer. Herein, the incident electromagnetic wave may be first shielded by the electromagnetic wave shielding layer 10. Specifically, the electromagnetic wave shielding layer 10 may change the electromagnetic wave incident on the surface thereof into current, and allow the current to flow along the surface, thereby preventing the electromagnetic wave from being transmitted into the electronic device. The electromagnetic wave shielding layer 10 can shield most of the electromagnetic wave. However, some of the incident electromagnetic wave, which is not shielded by the electromagnetic wave shielding layer, may pass through the electromagnetic wave shielding layer.

However, unlike conventional technology, in the present invention, even though the electromagnetic wave passes through the electromagnetic wave shielding layer 10, the electromagnetic wave passing through the electromagnetic wave shielding layer is absorbed by the electromagnetic wave absorbing layer 20 laminated on one side of the electromagnetic wave shielding layer, thereby protecting the electronic device from electromagnetic interference.

Specifically, the electromagnetic wave absorbing layer 20 contains ferrite particles, that is, a magnetic material having high magnetic permeability. Within the ferrite particles, fine electric or magnetic dipoles are randomly distributed. When the electromagnetic wave is incident to the ferrite particles in which such electric or magnetic dipoles exist, the dipoles are aligned by electromagnetic induction by the incident electromagnetic wave. Herein, dipoles of the ferrite particles are aligned by mainly absorbing a magnetic wave portion of the electromagnetic wave. In the alignment, the dipoles resist in a desired form according to the electromagnetic wave. When the dipoles are aligned by the electromagnetic wave by overcoming such resistance, the energy of the electromagnetic wave disappears via conversion into heat. It can be said that the electromagnetic wave absorbing layer 20 mainly shields the magnetic wave portion of the electromagnetic wave.

Also, when an electromagnetic wave shielding layer 10 is contacted with the outer surface of electronic device, and an electromagnetic wave absorbing layer 20 is laminated on the outer surface of the electromagnetic wave shielding layer 10, an electromagnetic wave generated from the outside of the electronic device is incident to the electromagnetic wave absorbing layer 20. The incident electromagnetic wave is first absorbed by the electromagnetic wave absorbing layer 20 and then disappears through heat conversion. Herein, even though some of the electromagnetic wave passes through the electromagnetic wave absorbing layer, the electromagnetic wave passing through electromagnetic wave absorbing layer may be emitted to the outside through current conversion by the electromagnetic wave shielding layer 10 laminated on one side of the electromagnetic wave absorbing layer.

As described above, an electromagnetic interference suppressing sheet 1 (see FIGS. 1 to 6) according to the present invention includes both an electromagnetic wave shielding layer 10 containing an electro-conductive material, and an electromagnetic wave absorbing layer 20 containing ferrite particles. Accordingly, it is possible to shield and absorb an electromagnetic wave generated from an external device, which is transmitted into an electronic device, as well as an electromagnetic wave generated from the inside of the electronic device, which is emitted to the outside, thereby protecting the electronic device from the electromagnetic wave.

According to an embodiment of the present invention, as shown in FIG. 1, an electromagnetic interference suppressing hybrid sheet 1 includes an electromagnetic wave shielding layer 10 and an electromagnetic wave absorbing layer 20.

The electromagnetic wave shielding layer 10 includes an electro-conductive material. Examples of the electro-conductive material include, but are not limited to, Al, Cu, Ni, Ag, Au, amorphous metal alloy, Ni—Fe alloy, Fe—Ni—Mo alloy, Fe—Si—Al alloy, Fe—Si alloy, Fe—Co alloy, etc. According to the kind of such an electro-conductive material, the volume resistivity of the electromagnetic wave shielding layer may be adjusted within a range of about 0.02 to 1×1012 Ω·cm. Therefore, it is possible to apply the hybrid sheet of the present invention to various electronic devices.

The thickness of such an electromagnetic wave shielding layer 10 may be adjusted according to an electronic device and a portion where a final electromagnetic interference suppressing hybrid sheet is applied, and is not particularly limited. In the present invention, on a thin electromagnetic wave shielding layer having a thickness of about 5 μm, even if some of an incident electromagnetic wave passes through the electromagnetic wave shielding layer, the electromagnetic wave passing through the electromagnetic wave shielding layer may be absorbed by an electromagnetic wave absorbing layer existing on one side of the electromagnetic wave shielding layer, thereby protecting an electronic device from the electromagnetic wave. According to an embodiment of the present invention, the thickness of the electromagnetic wave shielding layer may be within a range of about 7 to about 20 μm.

In the electromagnetic interference suppressing sheet 1 of the present invention, the electromagnetic wave absorbing layer 20 includes ferrite particles in order to absorb an electromagnetic wave and convert it to thermal energy.

The ferrite particles are magnetic oxides, and are classified into hard ferrite and soft ferrite by their magnetization extent. In the present invention, soft ferrite, of which magnetic property can be easily changed by an external factor (e.g., a magnetic field), is preferably used.

Examples of the ferrite particles include, but are not limited to, Ni—Zn based ferrite, Mn—Zn based ferrite, Mg—Zn based ferrite, Ni—Mn—Zn based ferrite, etc. According to an embodiment of the present invention, in absorbing an electromagnetic wave having a frequency band of about 100 KHz to about 1 GHz, Mn—Zn based ferrite may be used. Also, according to another embodiment of the present invention, in absorbing an electromagnetic wave having a frequency band of about 100 KHz to about 5 GHz, Ni—Zn based ferrite may be used. Also, according to a further embodiment of the present invention, in absorbing an electromagnetic wave having a frequency band of about 300 KHz to about 2 GHz, Mg—Zn based ferrite may be used.

Also, according to an embodiment of the present invention, ferrite particles represented by the following Formula 1 may be used, and an additive may be further included in such ferrite particles.

MnₓZn_{y}Fe_{z}O₄(x+y+z=3) [Formula 1]

Also, according to another embodiment of the present invention, ferrite particles represented by the following Formula 2 may be used, and an additive may be further included in such ferrite particles.

Mg₁₋ₓZnₓFe₂O₄(0≦x≦0.9) [Formula 2]

Also, according to a further embodiment of the present invention, ferrite particles represented by the following Formula 3 may be used, and an additive may be further included in such ferrite particles.

Ni₁₋ₓZnₓFe₂O₄(0≦x≦0.9) [Formula 3]

Examples of the additive may include, but are not limited to, cobalt oxide, silicon oxide, etc.

The shape of the ferrite particles is not particularly limited, but preferably is a plate-type shape or a needle-like shape. If the shape of the ferrite particles is another shape (for example, a spherical shape), instead of a plate-type shape or a needle-like shape, the magnetic permeability of the ferrite particles with a thickness (diameter) of about 100 μm or less is reduced, and thus a frequency band where the ferrite particles can be applied is limited. Also, such ferrite particles may have rapidly reduced absorbance efficiency at a high frequency band. According to an embodiment of the present invention, plate-type or needle-like ferrite particles having magnetic permeability within a range of about 40 to 400 may be used. According to another embodiment of the present invention, plate-type or needle-like ferrite particles having magnetic permeability within a range of about 30 to 50 may be used.

The thickness (length of a vertical section with respect to a longitudinal direction) of the plate-type or needle-like ferrite particles is within a range of about 2 to about 10 μm, preferably of about 5 to about 7 μm. If the thickness of the ferrite particles is less than about 2 μm, it is difficult to prepare and handle the ferrite particles. On the other hand, if the thickness of the ferrite particles is greater than about 10 μm, the density of a ferrite layer may be reduced, thereby degrading an electromagnetic wave absorbing property. Due to the plate-type or needle-like ferrite particles having such a thickness, an electromagnetic wave absorbing layer can have a thin thickness, and thus it is possible to fabricate a final electromagnetic interference suppressing hybrid sheet having a thin thickness.

Also, in the plate-type or needle-like ferrite particles, the length of a longitudinal direction is within a range of about 30 to about 100 μm, preferably of about 40 to about 80 μm. If the length of the ferrite particles is less than about 30 μm, magnetic permeability may be reduced, thereby reducing absorbing performance. On the other hand, if the length of the ferrite particles is greater than about 100 μm, the magnetic property may be reduced due to brittleness.

According to an embodiment of the present invention, in the plate-type or needle-like ferrite particles, the ratio of the length of a longitudinal direction to the thickness may be within a range of about 7 to about 12 μm.

The plate-type or needle-like ferrite particles may be prepared by various methods.

According to an embodiment of the present invention, the plate-type or needle-like ferrite particles may be prepared by the steps of: a) mixing iron oxide with metal oxide for forming ferrite; b) first sintering the mixture to obtain first sintered material; c) first mechanically grinding the first sintered material into ferrite fine powder; d) preparing dispersion solution by dispersing the ferrite fine powder in a solution including a binder resin dissolved in a solvent; e) coating the dispersion solution on the surface of a release film, and drying to form a coating layer, then detaching the coating layer from the surface of the release film; f) second sintering the detached coating layer to obtain second sintered material; and g) second mechanically grinding the second sintered material.

1) First, iron oxide and metal oxide for forming ferrite are mixed. Herein, the metal oxide for forming ferrite, which may be used in the present invention, is not particularly limited, but may include nickel oxide, manganese oxide, zinc oxide, magnesium oxide, etc. Also, as an additive, cobalt oxide, silicon oxide, etc. may be included.

Herein, it is preferable to use a mechanical mixing apparatus, such as a vibration mill or a ball mill, etc. so as to uniformly mix the iron oxide with metal oxide for forming ferrite. Also, the iron oxide and the metal oxide for forming ferrite may be mixed in a solvent.

The mixing ratio of the iron oxide and metal oxide for forming ferrite is adjusted according to components and physical properties of the final ferrite. For example, in Ni—Zn based ferrite, the metal oxide for forming ferrite (NiO, ZnO), and the iron oxide (Fe2O3) are preferably mixed in a molar ratio of 1:1. If the mixing ratio is out of the above mentioned range, the final ferrite may be insufficiently sintered or excessively sintered at a predetermined sintering temperature, thereby causing a change in sintered density and magnetic property.

2) Then, the mixture of the metal oxide for forming ferrite and the iron oxide is first sintered to obtain a sintered material (hereinafter, referred to as ‘a first sintered material’). Herein, the sintering temperature of the mixture (hereinafter, referred to as ‘a first sintering temperature’) may be adjusted according to the kind of metal oxide for forming ferrite and contents of the metal oxide and iron oxide, and is preferably within a range of about 850 to about 900° C. If the first sintering temperature is less than about 850° C., crystallization appropriate for a full magnetic property (a spinel structure) does not occur, thereby reducing the magnetic property, and on the other hand, if the first sintering temperature is greater than about 900° C., particles may excessively grow, and show non-uniform particle size distribution after a grinding process, thereby reducing the magnetic property.

3) The first sintered material is first mechanical ground by a mechanical grinding apparatus to obtain ferrite fine powder. Examples of the mechanically grinding apparatus include, but are not limited to, a ball mill apparatus, a planetary mill apparatus, a stirred ball mill apparatus, a vibrating mill apparatus, etc. Optionally, the first mechanical grinding of the first sintered material may be carried out in a solvent, and then, the formed ferrite fine powder may be subjected to drying. The solvent is not particularly limited, and examples of the solvent may include stearic acid, acetone, tetrahydrofuran, methylene chloride, chloroform, dimethylformamide, N-methyl-2-pyrrolidone (NMP), cyclohexane, water, methyl ethyl ketone, ethyl alcohol, and mixtures thereof.

4) The above-formed ferrite fine powder is added to a solution including a binder resin dissolved in a solvent, and is uniformly dispersed to obtain a mixed solution of the ferrite fine powder and the binder resin, which is a dispersion solution. Herein, the content of the ferrite fine powder is preferably within a range of about 300 to about 500 parts by weight, based on 100 parts by weight of the binder resin. However, the present invention is not limited thereto. If the content of the ferrite fine powder is less than about 300 parts by weight, the density of a sheet may be reduced, thereby reducing the magnetic property, and on the other hand, if the content of the ferrite fine powder is greater than about 500 parts by weight, the mechanical strength of the sheet may be reduced.

Non-limiting examples of the binder resin that may be used in the present invention include polyvinyl alcohol, acrylic resin, polyurethane, etc. Also, non-limiting examples of the solvent include stearic acid, acetone, tetrahydrofuran, methylene chloride, chloroform, dimethylformamide, N-methyl-2-pyrrolidone (NMP), cyclohexane, water, methyl ethyl ketone, ethyl alcohol, and a mixture thereof.

5) Next, the mixed solution of the ferrite fine powder and the binder resin, which is a dispersion solution, may be coated on the surface of a peelable release film, and may be dried to form a coating layer. Then, the formed coating layer may be detached from the surface of the release film.

Herein, the thickness of the coated dispersion solution on the release film is preferably within a range of about 15 to about 20 μm. If the thickness of the coated dispersion solution is less than about 15 μm, the thickness of a sintered plate-type or needle-like ferrite material after the following second sintering step is about 5 μm or less, thereby reducing mechanical strength. In addition, in mixing plate-type or needle-like ferrite powder with the binder resin, the ferrite powder may be destroyed. On the other hand, if the thickness of the coated dispersion solution is greater than about 20 μm, the thickness of a sintered plate-type or needle-like ferrite material after the following second sintering step is about 10 μm or more, and thus the density of a sheet may be reduced, thereby reducing the magnetic property.

In coating the dispersion solution on the release film, a conventional coating method known in the art, such as dip coating, die coating, roll coating, comma coating, or a combination thereof, etc. may be used.

Non-limiting examples of the peelable release film include a silicone-coated polyethylene film, polypropylene film, or polyethylene terephthalate (PET) film, etc.

6) The coating layer detached from the release film is sintered again to obtain a sintered material (hereinafter, referred to as ‘a second sintering material’). Herein, a sintering temperature (hereinafter, referred to as ‘a second sintering temperature’) is higher than the above mentioned first sintering temperature, and is preferably within a range of about 1000 to about 1300° C. If the second sintering temperature is less than about 1000° C., the film is insufficiently fired, thereby reducing the magnetic property. On the other hand, if the second sintering temperature is greater than about 1300° C., the film is excessively fired, and thus particle size distribution may be non-uniform after a grinding step, thereby reducing the magnetic property.

7) Then, the above-obtained second sintered material may be mechanically ground by the above mentioned mechanical grinding apparatus again.

Through the above described processes, the ferrite particles have plate-type or needle-like shaped particles, instead of conventionally known spherical-type ferrite particles. The plate-type or needle-like ferrite particles have high density and high magnetic permeability, compared to conventionally known spherical ferrite particles. Accordingly, the electromagnetic wave absorbing performance of the present invention may be improved by including such plate-type or needle-like ferrite particles in an electromagnetic wave absorbing layer of the present invention.

In the present invention, the thickness of the electromagnetic wave absorbing layer including the ferrite particles is not particularly limited, but is preferably about 50 μm or more. In the present invention, on a thin electromagnetic wave absorbing layer, even if some of an incident electromagnetic wave passes through the electromagnetic wave absorbing layer, the electromagnetic wave may be shielded by an electromagnetic wave shielding layer existing on one side of the electromagnetic wave absorbing layer, thereby protecting an electronic device from the electromagnetic wave. According to an embodiment of the present invention, the thickness of the electromagnetic wave absorbing layer may be within a range of about 30 to about 300 μm. According to another embodiment of the present invention, the thickness of the electromagnetic wave absorbing layer may be within a range of about 30 to about 150 μm.

The electromagnetic wave absorbing layer 20 of the present invention may include a binder resin, besides the above mentioned ferrite particles. Herein, the content of the ferrite particles is not particularly limited, but may be within a range of about 400 to about 800 parts by weight, based on 100 parts by weight of the binder resin. If the content of the ferrite particles is less than about 400 parts by weight, the density of a sheet may be reduced, thereby reducing the magnetic property, and on the other hand, if the content of the ferrite particles is greater than about 800 parts by weight, the sheet cannot be used as a hybrid sheet due to reduced mechanical property.

Non-limiting examples of the binder resin that may be used in the present invention include polyvinyl alcohol, acrylic resin, polyurethane, CPE (chlorinated polyethylene), etc.

As described above, the electromagnetic interference suppressing hybrid sheet 1 of the present invention includes the electromagnetic wave absorbing layer 20 and the electromagnetic wave shielding layer 10 laminated on one side of the absorbing layer (see FIG. 1). Additionally, the electromagnetic interference suppressing hybrid sheet 1 may further include an insulation layer 30 and/or an adhesive layer 40.

According to another embodiment of the present invention, as shown in FIG. 2, the electromagnetic interference suppressing hybrid sheet 1 may include an insulation layer 30 (hereinafter, referred to as ‘a first insulation layer’) interposed between an electromagnetic wave absorbing layer 20 and an electromagnetic wave shielding layer 10.

According to a further embodiment of the present invention, as shown in FIG. 3, the electromagnetic interference suppressing hybrid sheet 1, besides the first insulation layer 30 existing between the electromagnetic wave shielding layer 10 and the electromagnetic wave absorbing layer 20, may further include another insulation layer 31 (hereinafter, referred to as ‘a second insulation layer’) laminated on the outer surface of at least one of the electromagnetic wave shielding layer and the electromagnetic wave absorbing layer, for example, the outer surface of the electromagnetic wave absorbing layer 20.

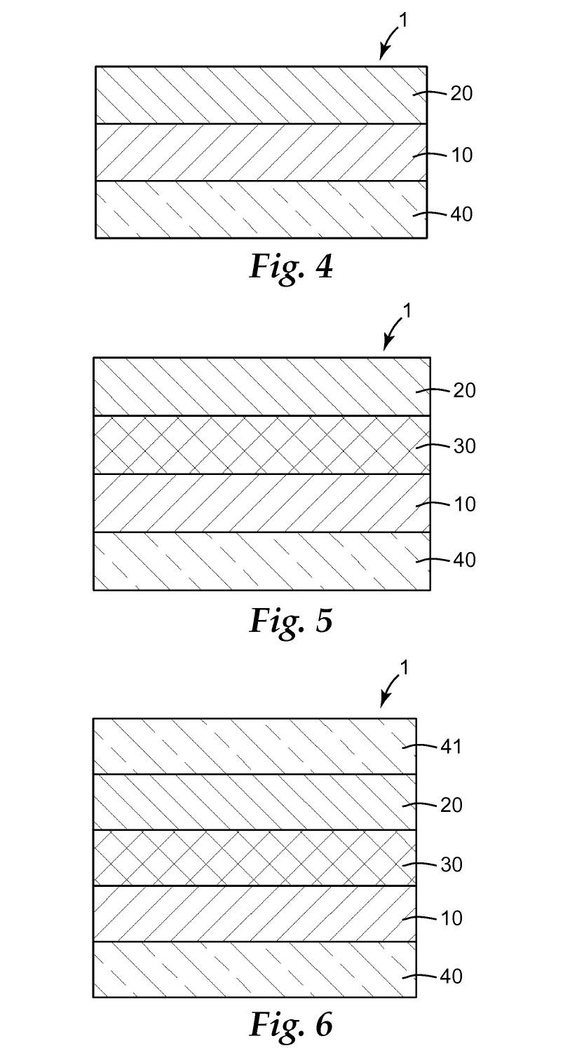

According to a still further embodiment of the present invention, as shown in FIGS. 4 and 5, the electromagnetic interference suppressing hybrid sheet 1 may further include an adhesive layer 40 (hereinafter, referred to as ‘a first adhesive layer’) laminated on the outer surface of at least one of the electromagnetic wave shielding layer 10 and the electromagnetic wave absorbing layer 20, for example, the outer surface of the electromagnetic wave shielding layer. The adhesive layer laminated on the outer surface of the electromagnetic wave shielding layer may be a conductive or non-conductive adhesive layer.

According to a yet further embodiment of the present invention, as shown in FIG. 6, the electromagnetic interference suppressing hybrid sheet 1 may include another adhesive layer 41 (hereinafter, referred to as ‘a second adhesive layer’) laminated on the outer surface of the electromagnetic wave absorbing layer 20.

Examples of a material for the first and second insulation layers that may be used in the present invention may include, but are not limited to, polyethylene terephthalate (PET), polyethylene, polypropylene, phenolic resin, melamine resin, polyimide, polyvinyl chloride, polyphenylene sulfide, silicon resin, epoxy resin, etc.

Examples of a material for the first and second adhesive layers that may be used in the present invention includes an adhesive polymer resin. A conductive adhesive layer may include conductive filler, as well as the adhesive polymer resin. Herein, the content of the conductive filler is not particularly limited, but is preferably within a range of about 20 to about 60 parts by weight, based on 100 parts by weight of the adhesive polymer resin.

In the present invention, as the adhesive polymer resin, an acrylic polymer resin may be used. According to an embodiment of the present invention, an acrylic polymer resin prepared by polymerization of a photopolymerizable monomer may be used.

In preparing such an acrylic polymer resin, as a photopolymerizable monomer, an alkyl acrylate ester monomer having a C1 to C14 alkyl group is usefully used. Non-limiting examples of the alkyl acrylate ester monomer include butyl(meth)acrylate, hexyl(meth)acrylate, n-octyl(meth)acrylate, isooctyl(meth)acrylate, 2-ethylhexyl(meth)acrylate, isononyl(meth)acrylate, etc. In addition, examples of the alkyl acrylate ester monomer include isooctyl acrylate, isononylacrylate, 2-ethyl-hexyl acrylate, decyl acrylate, dodecyl acrylate, n-butyl acrylate, hexylacrylate, etc.

The alkyl acrylate ester monomer may be used alone to form an acrylic adhesive resin, or may form an acrylic adhesive polymer resin through copolymerization with another polar copolymerizable monomer. In other words, the acrylic adhesive polymer resin may be prepared by copolymerization of an alkyl acrylate ester monomer having a C1 to C14 alkyl group and a polar copolymerizable monomer. Herein, the alkyl acrylate ester monomer and the polar copolymerizable monomer are preferably used in a weight ratio of 99:1 to 50:50, in consideration of physical properties of a final adhesive polymer resin. However, the present invention is not limited thereto.

Non-limiting examples of the polar copolymerizable monomer include acrylic acid, itaconic acid, hydroxyalkyl acrylate, cyanoalkyl acrylate, acrylamide, substituted acrylamide, N-vinyl pyrrolidone, N-vinyl caprolactam, acrylonitrile, vinyl chloride, diallyl phthalate, etc. Such polar copolymerizable monomer can provide adhesion and cohesiveness to a polymer resin, thereby improving the adhesive property.

Examples of the conductive filler that may be used in the present invention include: metal including noble metal and non-noble metal; noble metal and non-noble metal, alloyed with noble metal or non-noble metal; non-metal alloyed with noble metal or non-noble metal; conductive non-metal; and a mixture thereof.

Specifically, examples of the material for the conductive filler include: noble metal such as gold, silver, platinum, etc., and non-noble metal such as nickel, copper, tin, aluminum, etc.; noble metal and non-noble metal alloyed with noble metal, such as copper alloyed with silver, nickel alloyed with silver, aluminum alloyed with silver, tin alloyed with silver, gold alloyed with silver, etc.; noble metal and non-noble metal alloyed with non-noble metal such as copper alloyed with nickel, tin alloyed with nickel, etc.; non-metal alloyed with noble metal or non-noble metal, such as graphite, glass, ceramic, plastic, elastomer, mica, etc., alloyed with silver or nickel; conductive non-metal, such as carbon black, carbon fiber, etc.; and mixtures thereof.

An electromagnetic interference suppressing hybrid sheet 1 according to the present invention may be fabricated by using various methods.

According to an embodiment of the present invention, the electromagnetic interference suppressing hybrid sheet may be fabricated by the steps of: (i) forming an electromagnetic wave shielding layer by depositing or plating an electro-conductive material on a release film; (ii) adding and mixing ferrite particles in a polymer solution prepared by dissolving a binder resin in a solvent; and (iii) coating the mixture of the binder resin and the ferrite particles of step (ii) on the electromagnetic wave shielding layer of step (i), and carrying out a drying process.

1) First, an electromagnetic wave shielding layer is formed. Herein, an electro-conductive material may be deposited or plated on the surface of a release film by vacuum-deposition, ion plating, electron beam vacuum-deposition, sputtering, etc. in such a manner that the electromagnetic wave shielding layer is formed as a thin-film.

2) Then, a polymer solution is prepared by dissolving a binder resin in an appropriate organic solvent. Preferably, the solvent has solubility parameters similar to a binder resin to be used therein, which is to uniformly mix the materials and then to easily remove the solvent. Non-limiting examples of the solvent that may be used in the present invention include acetone, tetrahydrofuran, methylene chloride, chloroform, dimethylformamide, N-methyl-2-pyrrolidone (NMP), cyclohexane, water, methyl ethyl ketone, ethyl alcohol and a mixture thereof.

Also, examples of the binder resin include polyvinyl alcohol, acrylic binder, polyurethane, etc.

Also, the polymer solution may include plasticizer, etc. in order to improve the flexibility of a hybrid sheet. Examples of the plasticizer include phthalic acid ester plasticizer, trimellitic acid ester plasticizer, phosphoric acid ester plasticizer, epoxy plasticizer, polyester plasticizer, aliphatic acid ester plasticizer, etc., and more specifically include DBP(Di-butyl-phthalate), DOP(Di-2-ethylhexyl phthalate), DINP(Di-isononyl phthalate), DIDP(Di-isodecyl phthalate), BBP(Butyl benzyl phthalate), TOTM(Triethylhexyl trimellitate), TINTM(Tri-isononyl trimellitate), TIDTM(Tri-isodecyl trimellitate), TCP(Tri-cresyl phosphate), TOP(Tri-2-ethylhexyl phosphate), CDP(cresyl diphenyl phosphate), DOA(di-2-ethylhexyl adipate), DOZ(di-2-ethylhexyl azelate), DIDA(di-isodecyl adipate), etc.

3) Ferrite particles are added and dispersed in the prepared polymer solution to prepare a mixture of the ferrite particles and the binder resin. Herein, in order to uniformly mix the ferrite particles and the binder resin, a mechanical mixing apparatus known in the art, such as a ball mill apparatus, may be preferably used.

4) The prepared mixture of the ferrite particles and the binder polymer resin is coated on the previously prepared electromagnetic wave shielding layer, and is subjected to drying to obtain the electromagnetic interference suppressing hybrid sheet of the present invention.

Herein, in coating the mixture of the ferrite particles and the binder resin on the electromagnetic wave shielding layer, a conventional coating method known in the art, such as dip coating, die coating, roll coating, comma coating, or a combination thereof, may be used.

Furthermore, the present invention may provide various electronic devices/components including the above mentioned electromagnetic interference suppressing hybrid sheet, such as IC Package, PCB, etc.

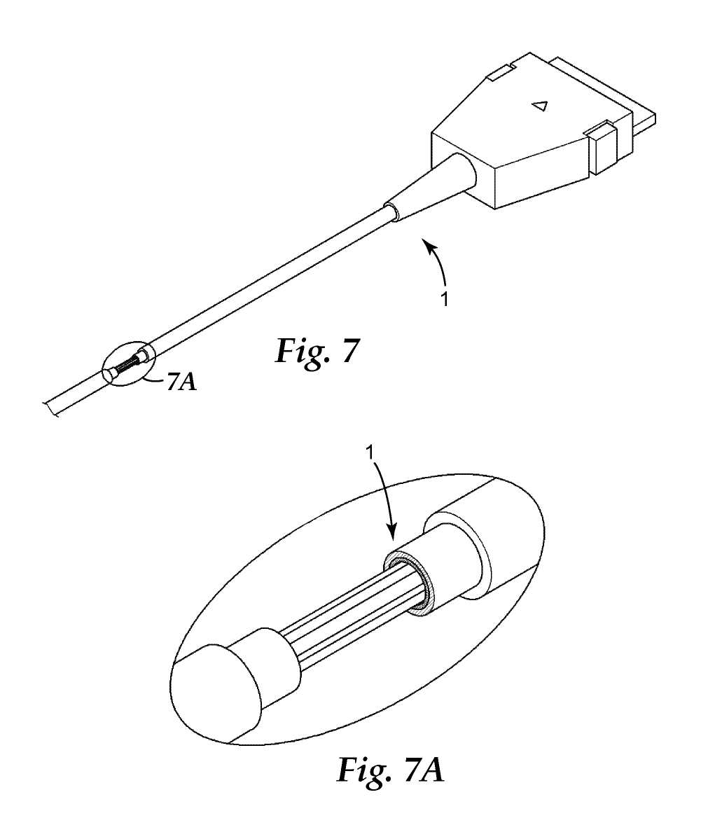

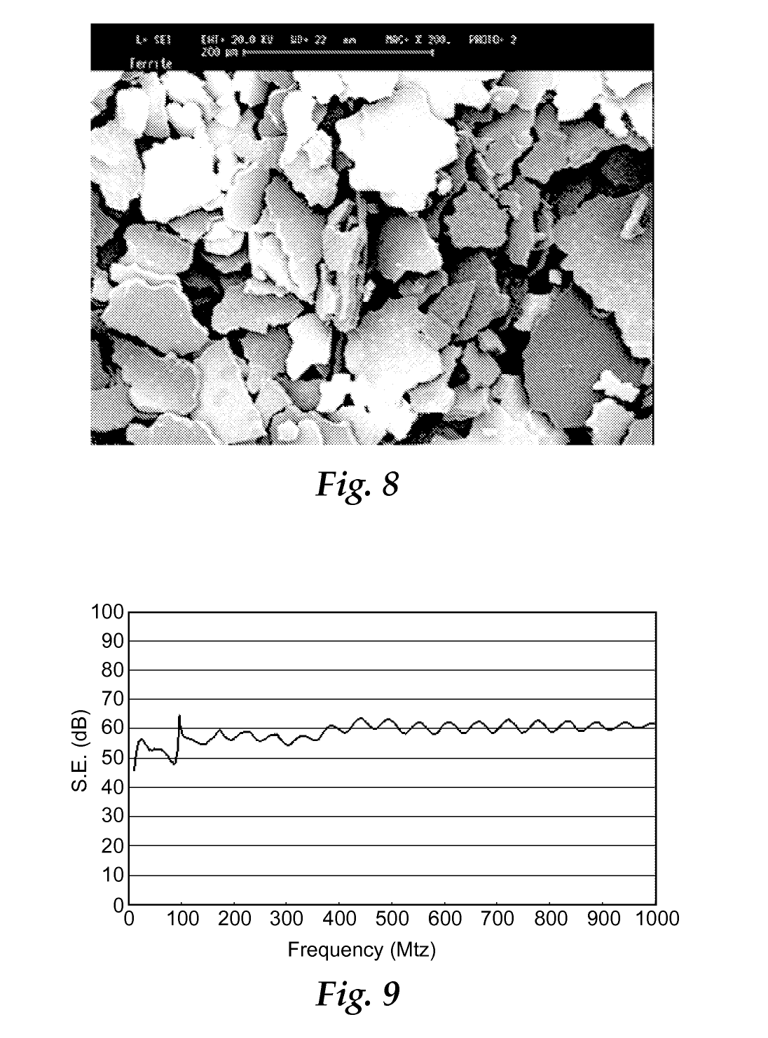

As shown in FIGS. 7 and 7A, in a cable 2 according to an embodiment of the present invention, an electric wire is covered with the above described electromagnetic interference suppressing hybrid sheet 1. The electromagnetic interference suppressing hybrid sheet can suppress or reduce unnecessary high frequency current conducted on a signal cable by impedance matching, and thus may be used for a high capacity data cable, such as a USB 2.0 cable, a USB 3.0 cable, an HDMI cable, etc. Also, high frequency current generated from an external device or terminal may be suppressed by the hybrid sheet.

### EXAMPLES

Reference will now be made in detail to the preferred embodiments of the present invention. However, the following examples are illustrative only, and the scope of the present invention is not limited thereto.

### Example 1

### 1-1 Preparation of Ferrite Particles

In 300 l of distilled water as a solvent, iron oxide (Fe₂O₃), nickel oxide (NiO), and zinc oxide (ZnO) were added in a molar ratio of 1:0.25:0.65, were uniformly mixed, and then were dried at 300° C. The dried mixture was sintered at about 880° C. to obtain a sintered material. In a ball-mill apparatus (NANOINTECH, Ball mill), the sintered material was mechanically ground with stainless steel balls (diameter=about 20 mm) at a rotation rate of about 24 rpm for 24 hours to obtain a fine powder (a weight ratio of the sintered material to the stainless steel balls is 0.2:1). Then, in a solution prepared by dissolving 100 parts by weight of polyvinyl alcohol (as a binder resin) in methyl ethyl ketone (as a solvent), 500 parts by weight of the fine powder was added, and was uniformly mixed to form a mixed solution. Next, the mixed solution was coated on the surface of a polyethylene terephthalate (PET) film with a thickness of about 18 μm, and was dried to form a coating layer. Then, the formed coating layer was detached from the PET film, and the detached coating layer was sintered at about 1150° C. to obtain a sintered material. In a ball-mill apparatus (NANOINTECH, Ball mill), the sintered material was mechanically ground with stainless steel balls (diameter=about 20 mm) at a rotation rate of about 24 rpm for 8 hours to obtain a ferrite particles (a weight ratio of the sintered material to the stainless steel balls is 0.2:1). The above-obtained ferrite particles has a plate-type shape with a thickness of about 5 μm, and a length of a longitudinal direction of about 70 μm.

### 1-2 Fabrication of an Electromagnetic Interference Suppressing Hybrid Sheet

On a polyethylene terephthalate (PET) film, an aluminum thin film with a thickness of about 7 μm was deposited onto a first surface by sputtering an Al target.

In methyl ethyl ketone as a solvent, 100 parts by weight of polyvinyl alcohol (as a binder resin) was dissolved. The above prepared ferrite particles were added to the solution, and were agitated to obtain a mixed solution.

Then, the formed mixed solution was coated onto the second surface of the PET film, of which the first surface was deposited with the aluminum thin film, with a thickness of 80 μm and was dried to obtain an electromagnetic interference suppressing hybrid sheet.

### Comparative Example 1

In methyl ethyl ketone as a solvent, 100 parts by weight of polyvinyl alcohol (as a binder resin) was dissolved. The ferrite particles prepared from Example 1 were added to the solution, and were agitated to obtain a mixed solution. Then, the formed mixed solution was coated to a thickness of 80 μm on a surface of a PET film, and was dried to obtain an electromagnetic wave absorbing sheet.

### Comparative Example 2

On a polyethylene terephthalate (PET) film, an aluminum thin film with a thickness of about 7 μm was deposited by sputtering Al target to obtain an electromagnetic wave shielding sheet.

### Experimental Example 1

### Determination on the Performance of an Electromagnetic Interference Suppressing Hybrid Sheet

In order to determine the electromagnetic wave shielding ability of an electromagnetic interference suppressing hybrid sheet of the present invention, the following tests were carried out.

### (1) Shielding Effectiveness (SE)

In accordance with ASTM D 4935, the shielding effectiveness (SE) of the electromagnetic interference suppressing hybrid sheet obtained from Example 1 was tested. The test system was used in frequency band of 10 MHz to 1 GHz. Herein, on sheets obtained from Comparative Examples 1 and 2 as control groups, the shielding effectiveness was tested. The test results are shown in Table 1 and FIG. 9.

Herein, the shielding effectiveness (SE) was calculated by the following Mathematical Formula 1.

SE=10 log(P₁/P₂)(decibels,dB) [Mathematical Formula 1]

In Mathematical Formula 1, P₁ indicates transmission power when a test sample exists, and P₂ indicates transmission power when a test sample does not exist.

Meanwhile, when a transmission reader displays the results in volts, the shielding effectiveness (SE) may be calculated by the following Mathematical Formula 2.

SE=20 log(V₁/V₂)(decibels,dB) [Mathematical Formula 2]

In Mathematical Formula 2, V₁ indicates transmission voltage when a test sample exists, and V₂ indicates transmission voltage when a test sample does not exist.

According to the results, the sheet of Comparative Example 1 showed low shielding effectiveness of about 5 dB, while, as shown in FIG. 9, the sheet obtained from Example 1 showed shielding effectiveness of Min 50 dB. Accordingly, it is determined that the electromagnetic interference suppressing hybrid sheet according to the present invention has an excellent electromagnetic shielding property.

### (2) Test on Power Loss

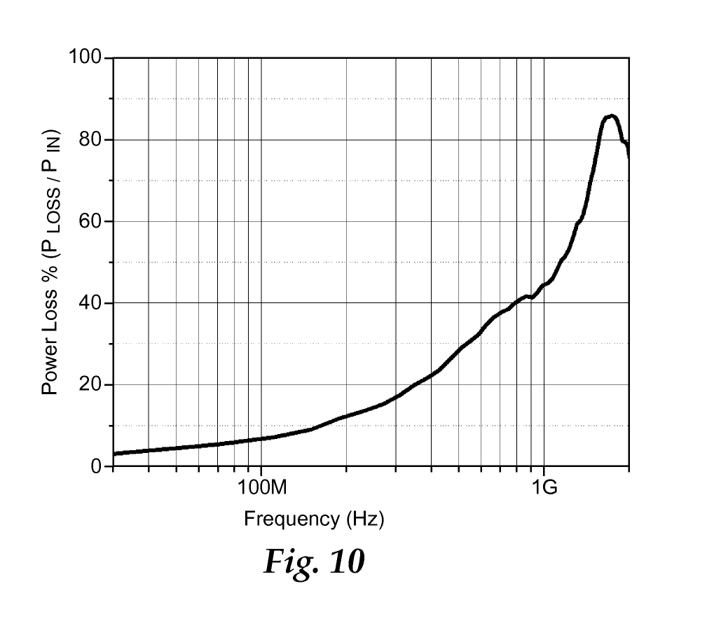

In order to determine the electromagnetic wave absorbing ability of the electromagnetic interference suppressing hybrid sheet of the present invention, the extent of power loss of the electromagnetic interference suppressing hybrid sheet obtained from Example 1 was tested. Also, on the sheet of Comparative Example 1 as a control group, the extent of power loss was tested. Herein, a test sample had a size of 50 mm (L) and 50 mm (W), and the test system was used in a frequency band of 30 MHz to 2 GHz. The test results are shown in Table 1 and FIG. 10.

According to the results, the sheet of Comparative Example 1 showed a low extent of power loss of about 15% at 1 GHz, while the hybrid sheet obtained from Example 1 showed a high extent of power loss of about 40% at 1 GHz (see Table 1, and FIG. 10). Accordingly, it is determined that the electromagnetic interference suppressing hybrid sheet according to the present invention has an excellent electromagnetic absorbing property.

### (3) Test on the Volume Resistivity

The volume resistivity of the electromagnetic interference suppressing hybrid sheet obtained from Example 1 was tested in accordance with ASTM D 257. Herein, on sheets of Comparative Examples 1 and 2 as a control group, the volume resistivity was tested. The test results are noted in Table 1.

According to the results, in the hybrid sheet obtained from Example 1, a volume resistivity of the electromagnetic wave absorbing layer thereof was similar to that of the sheet obtained in Comparative Example 1 (1×1012 Ω·cm); and a volume resistivity of the electromagnetic wave shielding layer thereof was similar to that of the sheet obtained in Comparative Example 2 (0.02 Ω·cm).

### (4) Test on the Magnetic Permeability

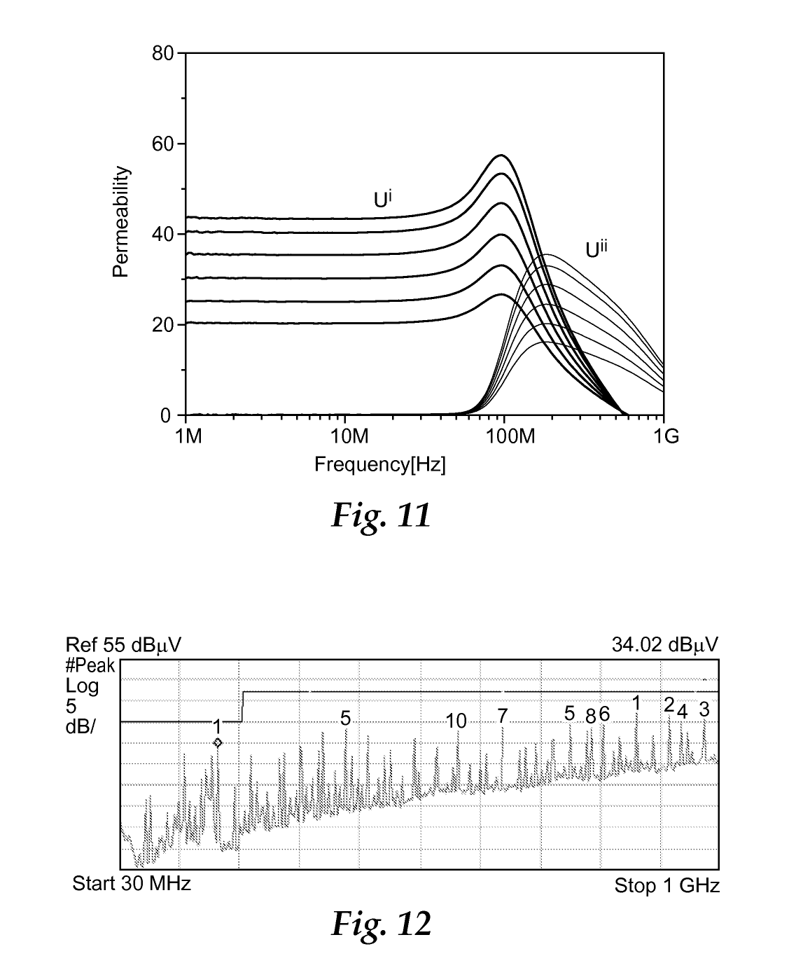

In the electromagnetic interference suppressing hybrid sheet obtained from Example 1, complex permeability (μ′: real part, μ″: imaginary part) was tested. The test results are shown in FIG. 11. Herein, as a control group, complex permeability of the sheet obtained from Comparative Example 1 was tested. The test results are shown in Table 1. A used test sample had a toroidal shape having inside diameter of 6 mm, outside diameter of 28 mm, and thickness of 8 mm, and the test system was used at a frequency band of 1 MHz to 1 GHz.

According to the results, the sheet of Comparative Example 1 had a real part (μ′) of about 15 in the complex permeability, while the hybrid sheet obtained from Example 1 had a real part (μ′) of about 20 to 45 in the complex permeability, which is higher that Comparative Example 1. Accordingly, it is determined that the electromagnetic interference suppressing hybrid sheet according to the present invention has an excellent electromagnetic absorbing property.

TABLE 1

| | | Comp. | Comp. |
|---|---|---|---|
| | Exp. 1 | Exp. 1 | Exp. 2 |
| Shielding effectiveness (dB) | Min 50 | 5 | 50 |
| (30 MHz~1 GHz) | | | |
| Real part (μ′) in permeability | 20~45 | 15 | — |
| Power loss (%) | 40 | 15 | — |
| (at 1 GHz) | | | |
| Volume resistivity | 0.02~1 × 1012 | 1 × 1012 | 0.02 |
| (Ω · cm) | | | |
| Operation temperature (° C.) | −20 to 90 | −20 to 90 | −20 to 90 |

### Experimental Example 2

### Determination on Suppression of Radiation-Noise in the USB 2.0 Data Cable

In order to determine the suppression of the Radiation-Noise in the USB 2.0 Data Cable using the electromagnetic interference suppressing hybrid sheet obtained from Example 1, the following tests were carried out.

The electromagnetic interference suppressing hybrid sheet obtained from Example 1 was wrapped around the USB 2.0 Data Cable. Next, an electronic terminal was contacted with the Data Cable, and noise radiated when power source drive was tested by using the Anechoic Chamber (3 m×3 m). The test results are shown in FIG. 12.

According to the results, for the Data Cable using the electromagnetic interference suppressing hybrid sheet obtained from Example 1, the Radiation-Noise was suppressed, and then the Radiation-Noise levels corresponded with FCC (Federal Communication Commission). Accordingly, it is determined that the electromagnetic interference suppressing hybrid sheet according to the present invention has an excellent high-frequency current suppression property in the data cable.

Although several exemplary embodiments of the present invention have been described for illustrative purposes, those skilled in the art will appreciate that various modifications, additions and substitutions are possible, without departing from the scope and spirit of the invention as disclosed in the accompanying claims.

1. An electromagnetic interference suppressing hybrid sheet comprising:
an electromagnetic wave shielding layer containing an electro-conductive material; and
an electromagnetic wave absorbing layer containing ferrite particles, which is laminated on one side of the electromagnetic wave shielding layer.

2. The electromagnetic interference suppressing hybrid sheet as claimed in claim 1, wherein the ferrite particles have a plate-type shape or a needle-like shape, and have a thickness (length of a vertical section with respect to a longitudinal direction) within a range of 2 to 10 μm, and a length of a longitudinal direction within a range of 30 to 100 μm.

3. The electromagnetic interference suppressing hybrid sheet as claimed in claim 2, wherein the ferrite particles of the plate-type shape or the needle-like shape have magnetic permeability within a range of 30 to 400.

4. The electromagnetic interference suppressing hybrid sheet as claimed in claim 2, wherein the ferrite particles are prepared by the steps of:
mixing iron oxide with metal oxide for forming ferrite;
first sintering the mixture to obtain first sintered material;
first mechanically grinding the first sintered material into ferrite fine powder;
preparing dispersion solution by dispersing the ferrite fine powder in a solution prepared by dissolving a binder resin in a solvent;
coating the dispersion solution on a surface of a release film, and drying to form a coating layer, then detaching the coating layer from the surface of the release film;
second sintering the detached coating layer to obtain second sintered material; and
second mechanically grinding the second sintered material.

5. The electromagnetic interference suppressing hybrid sheet as claimed in claim 4, wherein the metal oxide for forming the ferrite is selected from the group including nickel oxide, manganese oxide, zinc oxide, and a mixture thereof.

6. The electromagnetic interference suppressing hybrid sheet as claimed in claim 1, wherein the ferrite particles are selected from the group including Ni—Zn based ferrite, Mn—Zn based ferrite, Mg—Zn based ferrite, and Ni—Mn—Zn based ferrite.

7. The electromagnetic interference suppressing hybrid sheet as claimed in claim 1, wherein the electro-conductive material is selected from the group including Al, Cu, Ni, Ag, Au, amorphous metal alloy, Ni—Fe alloy, Fe—Ni—Mo alloy, Fe—Si—Al alloy, Fe—Si alloy, and Fe—Co alloy.

8. The electromagnetic interference suppressing hybrid sheet as claimed in claim 1, which comprises a first insulation layer interposed between the electromagnetic wave shielding layer and the electromagnetic wave absorbing layer.

9. The electromagnetic interference suppressing hybrid sheet as claimed in claim 1 or 8, which comprises a second insulation layer laminated on a surface of at least one of the electromagnetic wave shielding layer and the electromagnetic wave absorbing layer.

10. The electromagnetic interference suppressing hybrid sheet as claimed in claim 1 or 8, which comprises an adhesive layer laminated on a surface of at least one of the electromagnetic wave shielding layer and the electromagnetic wave absorbing layer.

11. The electromagnetic interference suppressing hybrid sheet as claimed in claim 10, wherein the adhesive layer laminated on the surface of the electromagnetic wave shielding layer is a conductive adhesive layer.

12. The electromagnetic interference suppressing hybrid sheet as claimed in claim 9, which comprises an adhesive layer laminated on the second insulation layer.

13. A method of fabricating an electromagnetic interference suppressing hybrid sheet, the method comprising the steps of:
(i) forming an electromagnetic wave shielding layer by depositing or plating an electro-conductive material on a release film;
(ii) adding and mixing ferrite particles in a polymer solution prepared by dissolving a binder resin in a solvent; and
(iii) coating a mixture of the binder resin and the ferrite particles of step (ii) on the electromagnetic wave shielding layer of step (i), and carrying out a drying process.

14. A cable comprising the electromagnetic interference suppressing hybrid sheet as claimed in claim 1, the sheet covering inside or outside of an electric cable.
